(19) United States
(12) Patent Application Publication
(10) Pub. No.: US 2024/0388274 A1
(43) Pub. Date: Nov. 21, 2024

(54) BONDING STRUCTURE AND ACOUSTIC WAVE DEVICE

(71) Applicant: QUANZHOU SANAN INTEGRATED CIRCUIT CO.,LTD., Quanzhou (CN)

(72) Inventors: Zhonghe LIN, Quanzhou (CN); Minghui FANG, Quanzhou (CN); Yenfu LIN, Quanzhou (CN); Shiwei HUANG, Quanzhou (CN); Shengyu YANG, Quanzhou (CN)

(21) Appl. No.: 18/788,168

(22) Filed: Jul. 30, 2024

Related U.S. Application Data
(63) Continuation of application No. PCT/CN2023/141783, filed on Dec. 26, 2023.

(30) Foreign Application Priority Data
Dec. 30, 2022 (CN) 202211720003.3
Dec. 30, 2022 (CN) 202211740396.4

(51) Int. Cl. H03H 9/02; H03H 3/08; H03H 9/25

(52) U.S. Cl. CPC H03H 9/02574; H03H 3/08; H03H 9/02559; H03H 9/25

(57) ABSTRACT

A bonding structure and an acoustic wave device relate to the field of filters. The bonding structure includes a supporting substrate and a piezoelectric layer formed on the supporting substrate. The supporting substrate is made of a polycrystalline material, and a porosity of the supporting substrate is less than 0.0045% or greater than 0.6%. The bonding structure can effectively improve the generation of interference of spurious emission and improve the performance of the device.

### CROSS-REFERENCE TO RELATED APPLICATIONS

This application is a continuation of International Application No. PCT/CN2023/141783, filed on Dec. 26, 2023. The international Application claims priority to Chinese patent application No. 202211740396.4, filed to China National Intellectual Property Administration (CNIPA) on Dec. 30, 2022. The entire contents of the above-mentioned applications are incorporated herein by reference.

### TECHNICAL FIELD

The disclosure relates to the technical field of electronic devices, and more particularly to a bonding structure and an acoustic wave device.

### BACKGROUND

Surface acoustic wave (SAW) filters are extensively used in various communication apparatuses. In the future communication applications, it is urgent to improve the working stability of the SAW filters in order to adapt to various harsh external environments. However, traditional SAW filters have the characteristics of low Q value (<1000), low working frequency and frequency drift with the change of working temperature, which has been difficult to meet the requirements of radio frequency (RF) terminals in the increasingly crowded 5G era. Therefore, the traditional SAW filters must develop into temperature-compensated filters with high frequency and stable temperature characteristics.

A Temperature Compensated Surface Acoustic Wave (TC-SAW) filter which bonding a temperature compensation layer which can be used as to a supporting structure to improve the temperature characteristics. After adding the supporting structure, a thickness of the piezoelectric layer can be effectively reduced and the Q value of the device can be improved. Moreover, the supporting structure has a better thermal expansion coefficient, which can effectively improve the frequency drift phenomenon caused by temperature in the device. However, the supporting structure of the existing TC-SAW filter device is usually made of a material with high density and high sound velocity. Therefore, it will inevitably produce a lot of interference of spurious emissions while improving the temperature drift characteristics of the device.

### SUMMARY

The disclosure aims to provide a bonding structure, a preparation method of the bonding structure, an acoustic wave device, and a duplexer, which can effectively improve the generation of interference of spurious emission and improve the performance of devices.

In an aspect of the disclosure, the disclosure provides a bonding structure, which includes a supporting substrate and a piezoelectric layer formed on the supporting substrate. A material of the supporting substrate is a polycrystalline material, a porosity of the supporting substrate is less than 0.0045% or greater than 0.6%, and a number of grain boundary layers of the supporting substrate is greater than or equal to 3.

In this bonding structure, pores and grain boundaries in the polycrystalline material can absorb and attenuate the scattering of acoustic waves, so that surface acoustic waves (SAWs) can be consumed in the process of transmitting to an inner part or a lower surface of the supporting substrate, so that the acoustic waves reflected back to an upper surface can be significantly reduced, the generation of interference of spurious emission can be effectively improved, and the performance of the device can be improved.

In another aspect of the disclosure, the disclosure provides a preparation method of a bonding structure, which includes the following steps: providing a supporting substrate, where a material of the supporting substrate is a polycrystalline material, and a porosity of the supporting substrate is less than 0.0045% or greater than 0.6%; and bonding a piezoelectric layer on a supporting substrate to obtain a bonding structure.

In still another aspect of the disclosure, a compensation substrate is provided, which includes a supporting substrate and a piezoelectric layer formed on the supporting substrate. Specifically, the supporting substrate is made of a polycrystalline material, and a number of crystal grains in a unit area of the supporting substrate is greater than or equal to 6, the unit area is 100 micrometers (μm)×100 μm, and a number of grain boundary layers is greater than or equal to 3.

By arranging the supporting substrate under the piezoelectric layer, the compensation substrate provided by the disclosure can effectively reduce the thickness of the piezoelectric layer, improve the Q value of the acoustic wave device, and realize the technical improvement from the traditional SAW device to the temperature compensation SAW device with stable high frequency-temperature characteristics. Because the grain boundaries of the polycrystalline material absorb and attenuate the scattering of acoustic waves, SAWs are transmitted to the inner part or the lower surface of the supporting substrate, and the acoustic waves are consumed by the grain boundaries and the pores, and the acoustic waves reflected back to the surface are significantly reduced, thus reducing spurious emission. Therefore, spurious emission can be effectively reduced by setting the material of the supporting substrate as the polycrystalline material. By limiting the number of crystal grains per unit area, the size of crystal grains in the polycrystalline material can be controlled. By setting the number of crystal grains per unit area, on the one hand, it can avoid the problem that the grain size is too large, resulting in fewer grain boundaries, which makes the fabricated acoustic wave device prone to spurious emission; on the other hand, it can prevent the problem that the grain size is too small, which leads to the increase of pores and the decrease of the Q value of the device.

In even still another aspect of the disclosure, the disclosure provides a preparation method of a compensation substrate, which includes the following steps: providing a supporting substrate, where a material of the supporting substrate is a polycrystalline material, and a number of crystal grains in a unit area of the supporting substrate is greater than or equal to 6, and the unit area of the supporting substrate is 100 μm×100 μm; and bonding a piezoelectric layer on the supporting substrate to obtain the compensation substrate. According to the preparation method of the compensation substrate provided by the disclosure, the piezoelectric layer is bonded on the supporting substrate to obtain the compensation substrate, which can be applied to a temperature compensation acoustic wave device, effectively improve the frequency drift of the supporting substrate due to temperature, and improve the Q value of the device.

In further still another aspect of the disclosure, an acoustic wave device is provided, which includes a bonding structure and electrodes disposed on the bonding structure.

In even further still another aspect of the disclosure, a duplexer is provided, which includes a transmitting acoustic wave device and a receiving acoustic wave device, and the transmitting acoustic wave device and/or the receiving acoustic wave device adopt the above acoustic wave device.

The acoustic wave device provided by this disclosure can effectively improve the performance and greatly reduce the interference of spurious emission.

### BRIEF DESCRIPTION OF DRAWINGS

FIG. 1 illustrates a schematic structural diagram of a bonding structure provided by some embodiments of the disclosure.

FIG. 2 illustrates a first schematic structural diagram of the supporting substrate provided by some embodiments of the disclosure.

FIG. 3 is a second schematic structural diagram of the supporting substrate provided by some embodiments of the disclosure.

FIG. 4 is a third schematic structural diagram of the supporting substrate provided by some embodiments of the disclosure.

FIG. 5 is a fourth schematic structural diagram of the supporting substrate provided by some embodiments of the disclosure.

FIG. 6 is a fifth schematic structural diagram of the supporting substrate provided by some embodiments of the disclosure.

FIG. 7 is a sixth schematic structural diagram of a supporting substrate provided by some embodiments of the disclosure.

FIG. 8 is a schematic diagram of spurious emission measurement provided by some embodiments of the disclosure.

FIG. 9 is a schematic flowchart of a preparation method of the bonding structure provided by some embodiments of the disclosure.

FIG. 10 is another flowchart of the preparation method of the bonding structure provided by some embodiments of the disclosure.

FIG. 11 is a schematic structural diagram of an acoustic wave device provided by some embodiments of the disclosure.

FIG. 12 is a schematic structural diagram of the bonding structure provided by some embodiments of the disclosure.

Description of reference signs: 10—supporting substrate; 20—piezoelectric layer; 30—electrode; T—thickness of the supporting substrate; D—grain size.

### DETAILED DESCRIPTION OF EMBODIMENTS

The existing temperature compensation acoustic wave device usually adds a supporting structure to a piezoelectric layer. However, the existing supporting structure usually uses a material with high density and high sound velocity, which may cause a lot of spurious emissions during the use of the device. In order to solve the above problem, the disclosure provides a new bonding structure, which has a special polycrystalline structure, and an acoustic wave device adopting the bonding structure can not only meet basic functions of the acoustic wave device, but also improve spurious emission.

The specific structure of the new bonding structure will be elaborated and explained in detail below.

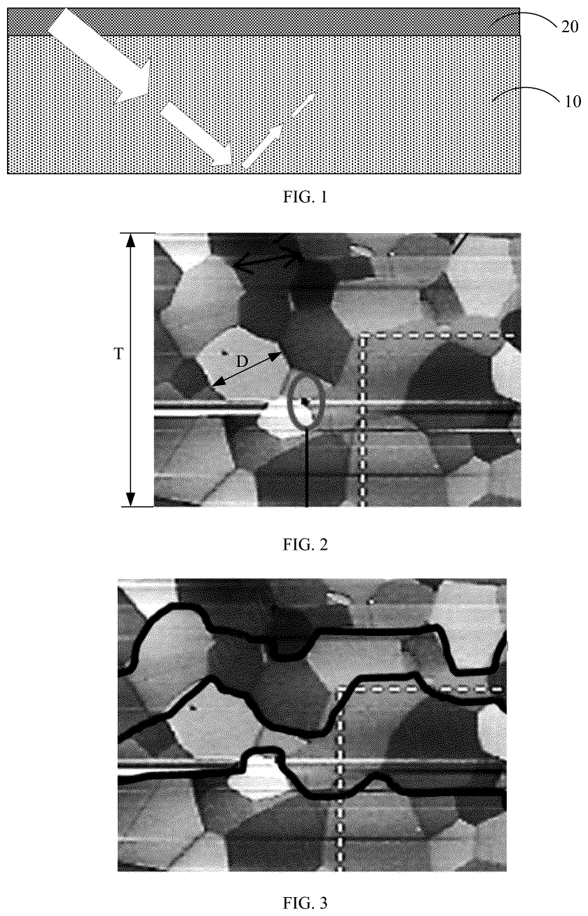

Referring to FIG. 1, a bonding structure provided by this embodiment includes a supporting substrate 10 and a piezoelectric layer 20 formed on the supporting substrate 10. The supporting substrate 10 is made of a polycrystalline material, and a porosity of the supporting substrate 10 is less than 0.0045% or greater than 0.6%. The bonding structure can effectively improve the generation of interference of spurious emission and improve the performance of the device.

Specifically, a material of the supporting substrate 10 is a polycrystalline material, and the polycrystalline material can be any one of polycrystalline spinel, polycrystalline sapphire, polycrystalline silicon, polycrystalline quartz, and polycrystalline aluminum nitride.

The piezoelectric layer 20 can be made of lithium tantalate (LT) or lithium niobate (LN).

It should be noted that the main reason for the attenuation of acoustic waves is the absorption of acoustic waves by a medium. Therefore, in the disclosure, the supporting substrate 10 is made of the polycrystalline material with a certain porosity. As shown in FIG. 2, some factors such as grain boundaries and micro-region inhomogeneities (i.e., pores) in the polycrystalline material can effectively reduce the energy of longitudinal wave transmission, thereby suppressing and attenuating spurious emission.

In this embodiment, the porosity of the supporting substrate 10 is less than 0.0045% or greater than 0.6%. For example, when the porosity of the supporting substrate 10 is less than 0.0045%, the specific porosity of the supporting substrate 10 can be 0.0044%, 0.0043%, 0.0040%, 0.0035%, 0.0030%, 0.0020%, or 0.0010%, etc., which will not be enumerated herein.

When the porosity of the supporting substrate 10 is greater than 0.6%, the specific porosity of the supporting substrate 10 can be 0.65%, 0.7%, 0.8%, 1.0%, 1.1%, 1.2%, 1.3%, or 1.4%, etc. Of course, the specific numerical value of the porosity of the supporting substrate 10 is only an example, and it is not a limitation on the specific porosity of the supporting substrate 10. Those skilled in the art can choose an appropriate porosity as long as the porosity is less than 0.0045% or greater than 0.6%.

In this embodiment, when the porosity of the supporting substrate 10 is greater than 0.6%. Preferably, the porosity of the supporting substrate 10 can be greater than 0.65%. In this way, the generation of spurious emission can be suppressed and attenuated more effectively.

In order to further suppress and attenuate interference of spurious emission and improve the performance of the device, in some embodiments, the porosity of the supporting substrate 10 is greater than 0.65% and less than 1.5%. For example, the porosity of the supporting substrate 10 can be 0.7%, 0.9%, 1.0%, 1.3%, or 1.4%, etc.

In addition, in this embodiment, the number of grain boundary layers of the supporting substrate 10 is greater than or equal to 3.

It should be noted that, the supporting substrate 10 is made of the polycrystalline material, in this situation, there are multiple crystal grains in the supporting substrate 10, as shown in FIGS. 2-3. Specifically, the grain boundary is a boundary between two adjacent grain layers, in FIG. 3, there are three grain boundary layers (the three grain boundary layers are marked with black lines in FIG. 3 respectively).

Due to the grain boundaries and the micro-region inhomogeneity (such as pores) in the medium, the acoustic waves can scatter at the interface of these regions and cause energy attenuation (scattering attenuation), and the number of grain boundary layers in the supporting substrate 10 are ubiquitous compared with the pores within the supporting substrate 10. Therefore, the grain boundary layer can effectively suppress and attenuate the acoustic waves propagating downward from the surface of the electrode 30.

The multiple grain boundaries of the supporting substrate 10 can absorb and attenuate the scattering of acoustic waves, and the acoustic waves transmitted by SAWs to the inner part or the lower surface of the supporting substrate 10 will be consumed by the grain boundaries and pores, so that the acoustic waves reflected back to the surface are significantly reduced, as shown in FIG. 1, thus reducing spurious emission.

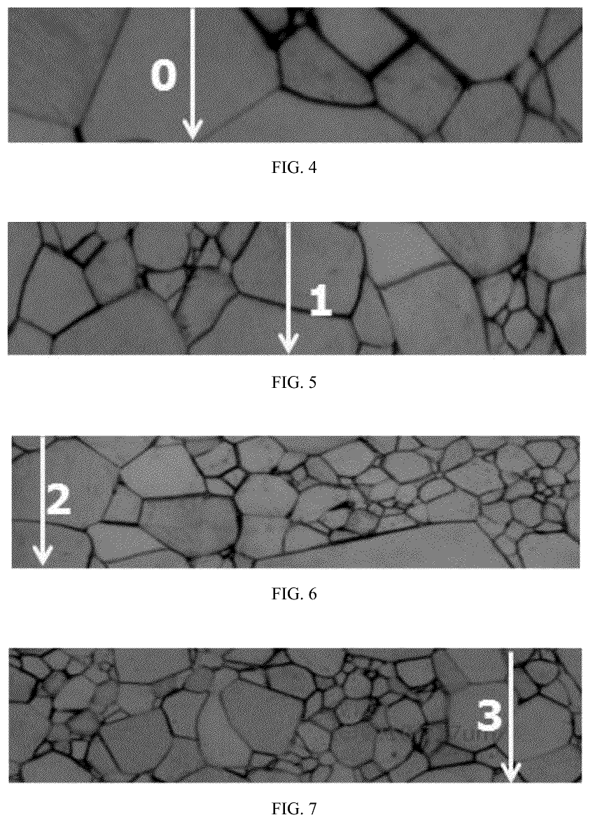

Referring to FIGS. 4 to 7, FIGS. 4 to 7 are diagrams when the number of grain boundary layers of the supporting substrate 10 is at least 0, 1, 2 and 3, respectively. Specifically, positions indicated by white arrows are the positions with the least grain boundary layer in side sections of four samples respectively. In this situation, the areas with fewer grain boundary layers correspond to larger grain sizes, and there are fewer crystal grains per unit area. The vicinity of the white arrows is essentially where there are the fewest crystal grains per unit area, which are 3, 4, 5, and 7 grains respectively. The characteristics of acoustic wave devices prepared with four kinds of supporting substrates 10 are shown in the following table.

| | Sample 1 | Sample 2 | Sample 3 | Sample 4 |
|---|---|---|---|---|
| Number of grain | ≥0 | ≥1 | ≥2 | ≥3 |
| boundary layers | | | | |
| Crystal grains | ≥3 | ≥4 | ≥5 | ≥7 |
| per unit area | | | | |
| Porosity | <0.0045% | <0.0045% | <0.0045% | <0.0045% |
| Spurious | 43% | 71% | 85% | 100% |
| emission yield | | | | |
| Mechanical | 8.75 | 8.5 | 8.5 | 8.6 |
| coupling | | | | |
| coefficient | | | | |
| Maximum | 1415 | 1669 | 1664 | 1507 |
| quality factor | | | | |

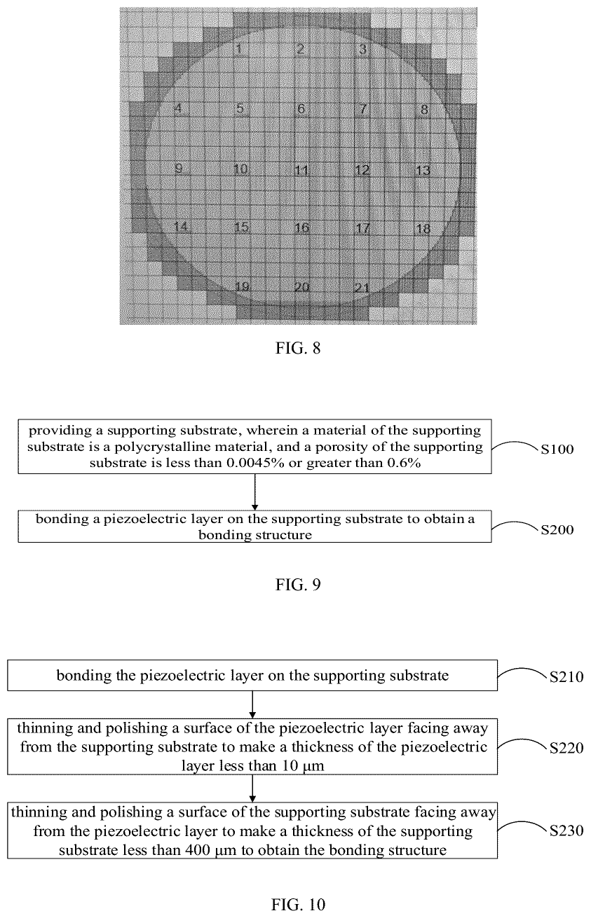

For a measurement method of spurious emission in the above table, please refer to FIG. 8. There are twenty-one positions are selected at fixed coordinate points of each sample to fabricate filters and test their characteristics. If there is no spurious emission generated at all twenty-one test points, the spurious emission yield will be 100% (as shown in the sample 4in the above table). If there is spurious emission in one position, the spurious emission yield can be calculated as 95% according to the proportion.

By analyzing the above table, it can be seen that of the four different samples have basically similar characteristics except for the obvious difference in the spurious emission. It can be seen that the number of grain boundary layers does have an impact on spurious emission, and by analyzing the table data, it can be known that when the number of grain boundary layers ≥3, it can better suppress the generation of spurious emission.

The number of grain boundaries in polycrystalline substrate is related to the size of the grains, especially the maximum grain size. Preferably, the number of the grain boundaries can be controlled by controlling the grain size of polycrystalline substrate. If the grain size is too large and there are few grain boundaries, the acoustic wave device is prone to spurious emission, while if the grain size is too small, although the grain boundaries increase, the porosity will also increase, which may reduce the Q value (i.e., quality factor) of the device while improving the spurious emission. Therefore, the number of grain boundary layers cannot be infinitely increased. In this embodiment, the number of grain boundary layers is optionally less than or equal to 40. Specifically, the specific number of grain boundary layers can be selected by those skilled in the art according to the actual situation, and the disclosure is not specifically limited.

In a specific embodiment, the supporting substrate 10 provided by the disclosure includes multiple crystal grains, and an average grain size of the crystal grains is in a range of 2 μm to 60 μm. Illustratively, the average particle size of the crystal grains can be 2 μm, 10 μm, 20 μm, 30 μm, 50 μm, or 60 μm, etc.

In this embodiment, the grain size can be in a range of 1 μm to 80 μm. For example, the grain size can be 1 μm, 5 μm, 20 μm, 40 μm, 50 μm, or 80 μm, etc.

The maximum grain size is related to the thickness T of the supporting substrate, and the number of grain boundary layers of the supporting substrate 10 in this embodiment needs to be greater than or equal to 3. In this situation, the maximum grain size should be less than or equal to one third of the thickness T of the supporting substrate.

In addition, in this embodiment, a thickness of the piezoelectric layer is in a range of 0.1 μm to 10 μm. In a specific embodiment, the thickness of the piezoelectric layer is in a range of 0.5 μm to 5 μm.

Moreover, the material of the supporting substrate 10 is the polycrystalline material, and the number of crystal grains in a unit area of the supporting substrate 10 is greater than or equal to 6, and the number of crystal grains in the unit area of the supporting substrate 10 is less than or equal to 200, wherein the unit area is 100 μm×100 μm.

Illustratively, the number of crystal grains per unit area of the supporting substrate 10 can be in a range of 10 to 100. Too many grains will increase the hardness of the supporting substrate 10, which is not conducive to the thinning and polishing of the supporting substrate 10, and will increase the material loss and processing time. However, too few grains can reduce the processing difficulty of the supporting substrate 10, but it will lead to the decrease of the material strength of the supporting substrate 10. Accordingly, in a specific embodiment, the number of crystal grains per unit area of the supporting substrate 10 is in a range of 10 to 30.

In conclusion, the bonding structure provided in this embodiment includes the supporting substrate 10 and the piezoelectric layer 20 formed on the supporting substrate 10. The supporting substrate 10 is made of the polycrystalline material, and the porosity of the supporting substrate 10 is less than 0.0045% or greater than 0.6%. In this embodiment, polycrystalline material is selected as the material of the supporting substrate 10, and the porosity of the supporting substrate 10 is less than 0.0045% or greater than 0.6%, so that the pores and grain boundaries in the polycrystalline material can absorb and attenuate the scattering of the acoustic waves, the SAWs can be consumed in the process of transmitting to the inner part or the lower surface of the supporting substrate 10, and then the acoustic waves reflected back to the upper surface can be significantly reduced, thereby reducing spurious emission and improving the performance of the device.

### Embodiment 1

A polycrystalline spinel supporting substrate 10 is selected and has the following characteristics: the porosity of supporting substrate 10 is in a range of 1% to 1.5%, the number of grain boundary layers is greater than 10 and less than or equal to 40, and the average particle size is about 6 μm.

The supporting substrate 10 is bonded to a piezoelectric layer 20, then thinning, polishing and other operations are carried out. Finally, a bonding structure with the thickness of the piezoelectric substrate 20 of 5 μm and the thickness T of the supporting substrate of 250 μm is obtained, and electrodes 30 are formed on the bonding structure to obtain an acoustic wave device and verify the characteristics of the acoustic wave device. Taking the characteristics of the acoustic wave device prepared by the supporting substrate 10 with porosity between 0.0045% and 0.6% as the reference standard, the obtained parameters are shown in the following table. A measurement method of spurious emission in the following table is similar to the above-mentioned measurement method illustrated in FIG. 8, which will not be repeated herein.

| | Reference | | | | | |
|---|---|---|---|---|---|---|
| | sample | Sample 5 | Sample 6 | Sample 7 | Sample 8 | Sample 9 |
| Spurious emission | 50% | 100% | 100% | 100% | 100% | 100% |
| yield | | | | | | |
| Mechanical coupling | 8.41 | 8.4 | 8.3 | 8.49 | 8.53 | 8.39 |
| coefficient | | | | | | |
| Maximum quality | 1565 | 1481 | 1485 | 1350 | 1177 | 1373 |
| factor | | | | | | |

According to the test results of the above table, it can be seen that the porosity is between 0.0045% and 0.6%, and the spurious emission can be significantly improved when the porosity of the supporting substrate 10 is selected between 1% and 1.5%.

In addition, when the porosity of the supporting substrate 10 is between 1% and 1.5%, the material strength will inevitably decrease due to the high porosity. In response to this situation, the average grain size of the supporting substrate 10 can be appropriately reduced. For example, the supporting substrate 10 with an average grain size of ≤4 μm can be selected, so that the grain size d of most crystal grains is in a range of 1 μm to 2 μm. In this way, the smaller the grain size D, the better the mechanical properties of the material. The macroscopic manifestations include increased yield and tensile strength, increased surface hardness, and extended fatigue life, etc. The concrete principle is that the finer the grains, the greater the number of crystal grains per unit volume, the more crystal grains participate in deformation, the more uniform the deformation, which allows for greater plastic deformation to occur before fracture. Both strength and ductility are increased, and the material consumes more work before fracture, thus it also has better toughness.

### Embodiment 2

A polycrystalline spinel supporting substrate 10 is selected and has the following characteristics: the porosity of supporting substrate 10 is in a range of 0.65% to 1%, the number of grain boundary layers is greater than 3 and less than or equal to 40, and the average particle size is about 45 μm.

The supporting substrate 10 is bonded to the piezoelectric layer 20, then thinning, polishing and other operations are carried out. Finally, a bonding structure with the thickness of the piezoelectric layer 20 of 5 μm and the thickness T of the supporting substrate of 250μm is obtained, and electrodes 30 are formed on the bonding structure to obtain an acoustic wave device and verify the characteristics of the acoustic wave device. Taking the characteristics of acoustic wave device prepared by the supporting substrate 10 with porosity between 0.0045% and 0.6% as the reference standard, the obtained parameters are shown in the following table.

| | Reference | Sample | Sample | Sample | Sample | Sample |
|---|---|---|---|---|---|---|
| | sample | 10 | 11 | 12 | 13 | 14 |
| Spurious emission | 50% | 100% | 100% | 100% | 100% | 100% |
| yield | | | | | | |
| Mechanical coupling | 8.41 | 8.6 | 8.5 | 8.5 | 8.39 | 8.45 |
| coefficient | | | | | | |
| Maximum quality | 1565 | 1525 | 1969 | 1964 | 1588 | 1573 |
| factor | | | | | | |

According to the test results of the above table, it can be seen that there is still a large interference of spurious emission when the porosity is between 0.0045% and 0.6%, and the spurious emission can be significantly improved when the porosity of the supporting substrate 10 is selected above 0.6%.

### Embodiment 3

A polycrystalline spinel supporting substrate 10 is selected and has the following characteristics: the porosity of the supporting substrate 10 is below 0.0045%, the number of grain boundary layers is greater than or equal to 10 and less than or equal to 40, and the average particle size is about 10 μm.

The supporting substrate 10 is bonded to the piezoelectric layer 20, then thinning, polishing and other operations are carried out. Finally, a bonding structure with the thickness of the piezoelectric layer 20 of 5 μm and the thickness T of the supporting substrate of 250μm is obtained, and electrodes 30 are formed on the bonding structure to obtain an acoustic wave device and verify the characteristics of the acoustic wave device. Taking the characteristics of the acoustic wave device prepared by the supporting substrate 10 with porosity between 0.0045% and 0.6% as the reference standard, the obtained parameters are shown in the following table.

| | Reference | | | | | | |
|---|---|---|---|---|---|---|---|
| | sample | Sample 15 | Sample 16 | Sample 17 | Sample 18 | Sample 19 | Sample 20 |
| Spurious emission | 50% | 100% | 100% | 100% | 100% | 100% | 100% |
| yield | | | | | | | |
| Mechanical coupling | 8.65 | 8.73 | 8.78 | 8.57 | 8.68 | 8.36 | 8.33 |
| coefficient | | | | | | | |
| Maximum quality | 1610 | 1652 | 1644 | 1369 | 1633 | 1553 | 1507 |
| factor | | | | | | | |

By analyzing the above table, it can be seen that there is still a large interference of spurious emission when the porosity is between 0.0045% and 0.6%, and the spurious emission can be significantly improved when the porosity of the supporting substrate 10 is selected below 0.0045%.

Through the above three embodiments, it can be proved that when the supporting substrate 10 is made of the polycrystalline material, and the porosity of the polycrystalline material is selected to be less than 0.0045% or greater than 0.6%, it can significantly improve the spurious emission, thus improving the performance of the device.

### Embodiment 4

Referring to FIG. 9, the disclosure provides a preparation method of a bonding structure, which includes the steps as follows.

S100, a supporting substrate 10 is provided. A material of the supporting substrate 10 is a polycrystalline material, and a porosity of the supporting substrate 10 is less than 0.0045% or greater than 0.6%.

S200, a piezoelectric layer 20 is bonded on the supporting substrate 10 to obtain the bonding structure.

It should be noted that the above-mentioned supporting substrate 10 is made of polycrystalline material, and the specific types of the polycrystalline material and the specific selection of the porosity of the polycrystalline material can be referred to by those skilled in the art based on the foregoing description, which will not be repeated herein.

Similarly, the specific material of the piezoelectric layer 20 can be referred to the foregoing description. As for the bonding process, as it is well known to those skilled in the art, it will not be repeated herein.

Referring to FIG. 10, the step S200 of bonding the piezoelectric layer 20 on the supporting substrate 10 to obtain the bonding structure includes the following steps.

S210, the piezoelectric layer 20 is bonded to the supporting substrate 10.

It should be noted that before bonding, a bonding surface of the piezoelectric layer 20 can be polished to make its roughness below 0.3 nanometers (nm). Similarly, a bonding surface of the supporting substrate 10 can be polished before bonding so that its roughness is below 0.8 nm.

During bonding, the bonding process can be carried out by ion activation at room temperature and high vacuum.

S220: a surface of the piezoelectric layer 20 facing away from the supporting substrate 10 is thinned and polished, so that a thickness of the piezoelectric layer 20 is less than 10 μm.

S230: a surface of the supporting substrate 10 facing away from the piezoelectric layer 20 is thinned and polished, so that a thickness T of the supporting substrate is less than 250μm, so as to obtain the bonding structure.

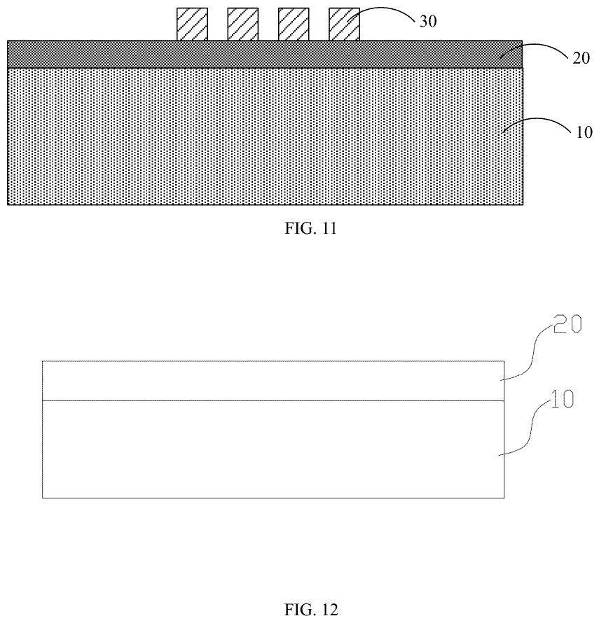

Referring to FIG. 11, the disclosure provides an acoustic wave device, which includes the bonding structure and electrodes 30 disposed on the bonding structure.

Specifically, the electrode 30 is an interdigital electrode 30, and since the specific structure of the bonding structure and its beneficial effects have been described in detail in the foregoing description, which will be not repeated herein.

In the disclosure, a duplexer is provided, which includes a transmitting acoustic wave device and a receiving acoustic wave device, and the transmitting acoustic wave device and/or the receiving acoustic wave device adopt the above acoustic wave device. As the specific structure of the acoustic wave device and its effective effect have been described in detail in the foregoing description, which will be not repeated herein.

### Embodiment 5

Referring to FIG. 12, the disclosure also provides a compensation substrate for an acoustic wave device, including a supporting substrate 10 and a piezoelectric layer 20 formed on the supporting substrate 10. A material of the supporting substrate 10 is a polycrystalline material, and the number of crystal grains in a unit area of the supporting substrate 10 is greater than or equal to 6, and the unit area is 100 μm×100 μm. In this embodiment, the number of crystal grains in the unit area of the supporting substrate 10 is greater than or equal to 6, and the specific number of crystal grains is not limited, which can be set by those skilled in the art as required. By arranging the supporting substrate 10 under the piezoelectric layer 20, the compensation substrate described in this embodiment can effectively reduce the thickness of the piezoelectric layer 20, improve the Q value of the acoustic wave device, and realize the technical improvement from the traditional SAW device to the temperature compensation SAW device with stable high frequency-temperature characteristics. As the grain boundaries of the polycrystalline material absorb and attenuate the scattering of the acoustic waves, the SAWs are transmitted to the inner part or the lower surface of the supporting substrate, and the acoustic waves are consumed by the grain boundaries and pores, and the acoustic waves reflected back to the surface are significantly reduced, thus reducing spurious emission. Therefore, spurious emission can be effectively reduced by setting the material of the supporting substrate 10 as the polycrystalline material. By limiting the number of crystal grains per unit area, the number of pores can be controlled, which can prevent the decrease of Q value of the device due to the increase of pores.

In some embodiments, the number of crystal grains in the unit area of the supporting substrate 10 is less than or equal to 200. In an embodiment, the supporting substrate 10 has a number of grains is greater than or equal to 6 and less than or equal to 200 in a unit area of 100 μm×100 μm. In a specific embodiment, the number of crystal grains of the supporting substrate 10 in a unit area of 100 μm×100 μm is 10-100. For example, the number of crystal grains of the supporting substrate 10 in a unit area of 100 μm×100 μm can be 10, 30, or 100.

In an elastic wave device using the above-mentioned bonding structure, the polycrystalline substrate has a number of grains of 10-100 in a unit area of 100 μm×100 μm which can effectively suppress spurious and ensure that the material strength is within a suitable range, thus the processing difficulty of the material will not be increased. If there are too many crystal grains, the hardness of the supporting substrate 10 will be increased, which is not conducive to thinning and polishing the supporting substrate 10, and will increase material loss and processing time. Therefore, by controlling the number of crystal grains, not only the spurious emission can be improved, but also the difficulty of production and processing can be effectively reduced. The specific number of crystal grains is not limited here, but can be set by those skilled in the art according to actual needs.

In some embodiments, the number of grain boundary layers is greater than or equal to 3; and/or the number of grain boundary layers is less than or equal to 40. By limiting the number of grain boundary layers, the arrangement of crystal grains in the cross section of the supporting substrate can be controlled. If the number of grain boundary layers is less than 3, it will lead to too few grain boundaries and cannot effectively absorb and consume sound waves, which is not conducive to the reduction of spurious emission. An excessive number of grain boundary layers can lead to an increase in the number of pores, resulting in a reduction of Q value of the device.

In some embodiments, the material of the supporting substrate 10 is any one of polycrystalline spinel, polycrystalline sapphire, polycrystalline silicon, polycrystalline quartz, and polycrystalline aluminum nitride.

In some embodiments, the piezoelectric layer 20 is made of a piezoelectric material and has a piezoelectric effect. The piezoelectric material is LT in the first embodiment, but in other embodiments of the disclosure, the piezoelectric material can also be LN. In this embodiment, the thickness of the piezoelectric layer is in a range of 0.1 to 10 μm, and in a specific embodiment, the thickness of the piezoelectric layer is in a range of 0.5 to 5 μm.

In this embodiment, a preparation method of a compensation substrate is provided, which includes the following steps: providing a supporting substrate 10, where a material of the supporting substrate 10 is a polycrystalline material, and the number of crystal grains in a unit area of the supporting substrate 10 is greater than or equal to 6, and the unit area of the supporting substrate 10 is 100 μm×100 μm; bonding a piezoelectric layer 20 to the supporting substrate 10 to obtain the compensation substrate.

Specifically, the piezoelectric layer 20 is bonded on a supporting substrate 10 to obtain the compensation substrate, including: the piezoelectric layer 20 is bonded on the supporting substrate 10; a surface of the piezoelectric layer 20 facing away from the supporting substrate 10 is thinned and polished in order to make a thickness of the piezoelectric layer 20 less than 10 μm; and a surface of the supporting substrate 10 facing away from the piezoelectric layer 20 is thinned and polished in order to make a thickness of the supporting substrate 10 less than or equal to 400 μm, so as to obtain the compensation substrate. In this situation, the compensation substrate with the thickness of the supporting substrate 10 between 150 and 250μm has good performance, for example, it can be 180-220 μm. By bonding the piezoelectric layer 20 to the supporting substrate 10 to obtain the compensation substrate, the compensation substrate can be applied to a temperature compensation acoustic wave device, which can effectively improve the frequency drift of the supporting substrate 10 due to temperature, and improve the Q value of the device.

Specifically, LT is selected as the piezoelectric layer 20, and one surface of the piezoelectric layer 20 is polished to a surface roughness of less than 0.3 nm, which is the bonding surface of the piezoelectric layer 20. Polycrystalline spinel is selected as the supporting substrate 10, and one surface of the supporting substrate 10 is polished to a surface roughness of less than 0.8 nm, which is the bonding surface of the supporting substrate 10. The bonding surfaces of the piezoelectric layer 20 and the supporting substrate 10 are bonded in a normal temperature and high vacuum environment by ion activation. Finally, the finished product is a compensation substrate with LT thickness of 5 μm and spinel thickness of 240μm.

In order to further illustrate the excellent performance of the acoustic wave device provided by the embodiment of the disclosure, tests are conducted with the acoustic wave devices provided by the disclosure.

### TEST EXAMPLE 1

In a specific test, the average grain size in the supporting substrate 10 is about 6 μm, and the number of grain boundary layers is greater than 10; the supporting substrate 10 has about 100 crystal grains in the area of 100 μm×100 μm, and the supporting substrate is bonded to the LT piezoelectric layer 20, and then thinning, polishing and other operations are carried out sequentially. Finally, the compensation substrate with the thickness of LT piezoelectric layer of 5 μm and spinel thickness of 250 μm is obtained. Using this compensation substrate to prepare the acoustic wave device, the final acoustic wave device is obtained and its characteristics are verified. There is no spurious emission, that is, the spurious emission yield is 100%.

### TEST EXAMPLE 2

In a specific test, the average grain size in the supporting substrate 10 is about 45 μm, and the number of grain boundary layers is greater than 3; the supporting substrate 10 has about 50 grains in the area of 100 μm×100 μm, and the supporting substrate 10 is bonded to the LT piezoelectric layer 20, and then thinning, polishing and other operations are carried out sequentially. Finally, the compensation substrate with the thickness of LT piezoelectric layer of 5 μm and spinel thickness of 250 μm is obtained. Using this compensation substrate to prepare the acoustic wave device, the final acoustic wave device is obtained and its characteristics are verified. Similarly, there is no spurious emission, that is, the spurious emission yield is 100%.

### TEST EXAMPLE 3

Compared with the test example 1, the supporting substrate 10 has about 3 grains in the area of 100 μm×100 μm, and the minimum number of grain boundary layers is 0. The final acoustic wave device is obtained and its characteristics are verified, and the spurious emission yield is 43%.

### TEST EXAMPLE 4

Compared with the test example 3, the supporting substrate 10 has about 5 grains in the area of 100 μm×100 μm, and the minimum number of grain boundary layers is 2. The final acoustic wave device is obtained and its characteristics are verified, and the spurious emission yield is 85%.

### TEST EXAMPLE 5

Compared with the test example 3, the supporting substrate 10 has about 7 grains in the area of 100 μm×100 μm, and the minimum number of grain boundary layers is 3. The final acoustic wave device is obtained and its characteristics are verified, and the spurious emission yield is 100%.

The foregoing is only illustrated embodiments of this disclosure, and is not intended to limit this disclosure. For those skilled in the art, this disclosure can be modified and varied. Any modification, equivalent substitution, improvement, etc. made within the spirit and principles of this disclosure should be included in the protection scope of this disclosure.

In addition, it should be noted that the specific technical features described in the above-mentioned specific embodiments can be combined in any suitable way without contradiction, and in order to avoid unnecessary repetition, various possible combinations are not explained in this disclosure.

What is claimed is:

1. A bonding structure, comprising:
a supporting substrate; and
a piezoelectric layer formed on the supporting substrate;
wherein a material of the supporting substrate is, a porosity of the supporting substrate is less than 0.0045% or greater than 0.6%, and a number of grain boundary layers of the supporting substrate is greater than or equal to 3.

2. The bonding structure as claimed in claim 1, wherein the porosity of the supporting substrate is greater than 0.65%.

3. The bonding structure as claimed in claim 2, wherein the porosity of the supporting substrate is greater than 0.65% and less than 1.5%.

4. The bonding structure as claimed in claim 1, wherein the number of the grain boundary layers is greater than or equal to 10.

5. The bonding structure as claimed in claim 4, wherein the number of the grain boundary layers is less than or equal to 40.

6. The bonding structure as claimed in claim 1, wherein the supporting substrate comprises a plurality of crystal grains, and an average grain size of the crystal grains is in a range of 2 μm to 60 μm.

7. The bonding structure as claimed in claim 1, wherein the material of the supporting substrate is any one selected from the group consisting of polycrystalline spinel, polycrystalline sapphire, polycrystalline silicon, polycrystalline quartz, and polycrystalline aluminum nitride.

8. The bonding structure as claimed in claim 1, wherein the supporting substrate comprises a plurality of crystal grains, and a maximum grain size of the crystal grains is less than or equal to one third of a thickness of the supporting substrate.

9. The bonding structure as claimed in claim 1, wherein a thickness of the piezoelectric layer is in a range of 0.1 μm to 10 μm.

10. The bonding structure as claimed in claim 1, wherein a number of crystal grains in a unit area of the supporting substrate is greater than or equal to 6, and the unit area is 100 μm×100 μm.

11. The bonding structure as claimed in claim 10, wherein the number of the crystal grains in the unit area of the supporting substrate is less than or equal to 200.

12. The bonding structure as claimed in claim 10, wherein the porosity of the supporting substrate is less than 0.0045% and greater than or equal to 0.001%.

13. The bonding structure as claimed in claim 1, wherein a roughness of a surface of the supporting substrate in contact with the piezoelectric layer is less than 0.8 nanometers (nm).

14. An acoustic wave device, comprising:
a supporting substrate, formed of a polycrystalline material, wherein the supporting substrate having a porosity of less than 0.0045% or greater than 0.6% and a number of grain boundary layers greater than or equal to 3;
a piezoelectric layer, formed on the supporting substrate; and
electrodes, disposed over the piezoelectric layer.

15. The acoustic wave device as claimed in claim 14, wherein the porosity of the supporting substrate is in a range of 1% to 1.5%.

16. The acoustic wave device as claimed in claim 15, wherein an average grain size of the supporting substrate is less than or equal to 4 μm.

17. The acoustic wave device as claimed in claim 16, wherein the number of grain boundary layers is greater than 10 and less than or equal to 40.

18. The acoustic wave device as claimed in claim 14, wherein the porosity of the supporting substrate is below 0.0045%, and the number of grain boundary layers is greater than or equal to 10 and less than or equal to 40.

19. The acoustic wave device as claimed in claim 18, wherein an average particle size is about 10 μm.

20. The acoustic wave device as claimed in claim 14, wherein the supporting substrate has a number of grains is greater than or equal to 6 and less than or equal to 200 in a unit area of 100 μm×100 μm.
